(19) United States
(12) Patent Application Publication
(10) Pub. No.: US 2005/0082666 A1
(43) Pub. Date: Apr. 21, 2005

(54) Liquid cooling device

(75) Inventors: Hsieh-Kun Lee, Tu-Cheng (TW); Cheng-Tien Lai, Tu-Cheng (TW); Shi-Wen Zhou, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 10/950,736

(22) Filed: Sep. 27, 2004

(30) Foreign Application Priority Data
Oct. 17, 2003 (TW) 92218498

(51) Int. Cl. F25B 41/00; H01L 23/34; H01L 23/48; H01L 23/52; H01L 29/40

(52) U.S. Cl. 257/728

(57) ABSTRACT

A liquid cooling device includes a casing (10) having a container (14) for accommodating liquid therein, a liquid inlet port (18) in communication with the container, and a diversion member (20, 20′) located in the casing, for leading liquid from the liquid inlet port to a bottom of the container.

### BACKGROUND OF THE INVENTION

1. Field of the Invention

The present invention relates to a cooling device, and more particularly to a cooling device for cooling a heat-generating device utilizing liquid.

2. Description of Related Art

Liquid cooling devices were commonly utilized to cool huge systems such as furnaces. Today, liquid cooling devices also are used to cool electronic or electrical components, such as chipsets, dies or computer central processing units (CPUs), by circulating the cooling liquid in a channel.

Generally, a liquid cooling device comprises a casing, forming a liquid container made of metal material. The casing comprises a base and a lid covering the base. The base is for contacting a cooled component. The lid comprises a liquid outlet and a liquid inlet Liquid pipes respectively connect the liquid outlet and the liquid inlet to a liquid tank. The liquid tank is further provided with a submersible motor therein. In operation to dissipate heat from the cooled component, the liquid in the liquid tank flows through the liquid inlet pipe into the casing, and is drawn by the motor to exit from the casing to the liquid tank for a subsequent circulation. U.S. Pat. No. 6,655,449 B1 shows such a device utilizing liquid cooling that is used to dissipate heat from a central processing unit or chipset of a computer.

It is apparent, the liquid directly strikes the base and rebound from the base without heat exchange with the base, and thus splashes in the casing. As a result, the liquid is unable to flow in an optimized route in the casing to get maximized heat exchange efficiency, especially when the container is flat.

### SUMMARY OF THE INVENTION

Accordingly, an object of the present invention is to provide a liquid cooling device getting improved liquid flow route for maximized heat exchange efficiency.

In order to achieve the object set out above, a liquid cooling device in accordance with a preferred embodiment of the present invention comprises a casing having a container for accommodating liquid therein, a liquid inlet port in communication with the container, and a diversion member located in the casing, for leading liquid from the liquid inlet port to a bottom of the container.

Other objects, advantages and novel features of the present invention will become more apparent from the following detailed description when taken in conjunction with the accompanying drawings, in which:

### BRIEF DESCRIPTION OF THE DRAWINGS

FIG. 1 is an assembled, isometric view of a liquid cooling device in accordance with the preferred embodiment of the present invention;

FIG. 2 is a view of a casing of the liquid cooling device of FIG. 1;

FIG. 3 is a cross-sectional view of FIG. 2, taken along III-III; and

FIG. 4 is a cross-sectional view of a casing of a liquid cooling device in accordance with an alternative embodiment of the present invention.

### DETAILED DESCRIPTION OF THE INVENTION

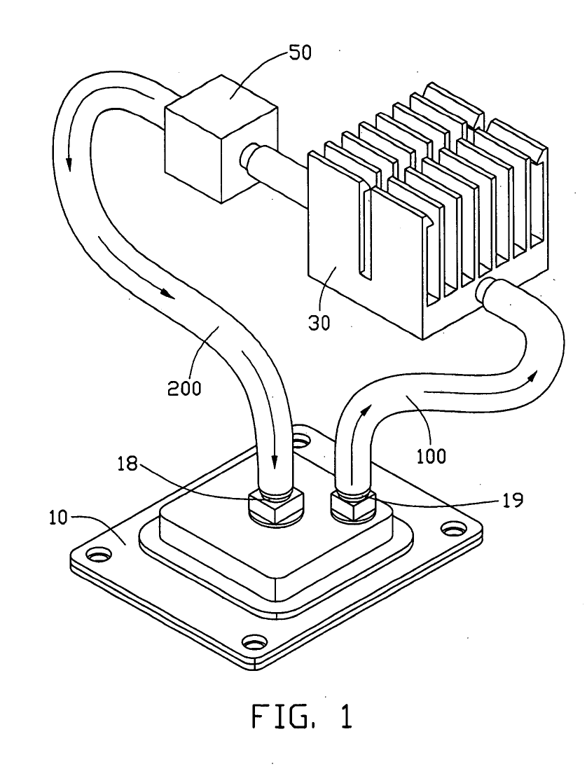

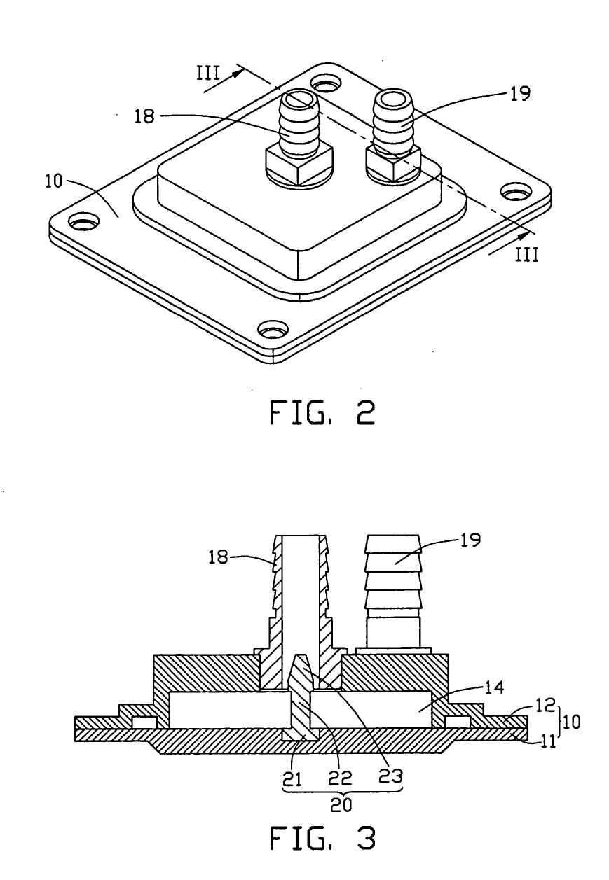

Referring to FIGS. 1-3, a liquid cooling device in accordance with the preferred embodiment of the present invention comprises a casing 10, and an actuator 50 connected to the casing 10 by a liquid outlet pipe 100 and a liquid inlet pipe 200 respectively at opposite locations of the actuator 50.

The casing 10 comprises a base 11 for intimately contacting a heat generating component or source (not shown) by a side surface thereof, and a lid 12 cooperating with the base 11 to form a container 14 therebetween to accommodate liquid for circulation. The base 11 and the lid 12 are hermetizated by calk packing, shim, or seal, for keeping the liquid from leaking out of the container 14. A pair of tubular connectors, for connecting the pipes 100, 200 to the casing 10, extends outwardly from the lid 12. The connectors are respectively named as liquid inlet port 18 and liquid outlet port 19, according to the directions along which the liquid flows in the connectors. The liquid inlet port 18 is disposed at a middle of the lid 12.

The container 14, the liquid outlet pipe 100, the actuator 50 and the liquid inlet pipe 200 cooperatively define a hermetical circulation route or loop for liquid. The actuator 50 can be a pump, an impeller, a promoter or the like, for actuating liquid to continuously circulate in the route along the arrow as shown in FIG. 1.

For promoting the cooling efficiency of the device, a radiator is arranged on the liquid circulation route. A fin member 30 is an example of the radiator. In the preferred embodiment of the present invention, a portion of the liquid outlet pipe 100 enters into the fin member 30, so that heat, still contained in the liquid after naturally cooled in the casing 10, is removed to the fin member 30 and is dissipated to ambient air. Thus, the liquid is extremely cooled before entering the container 14 for a subsequent circulation. Understandably, a fan (now shown) can be mounted onto the fin member 30 for enhancing heat dissipation capability of the fin member 30.

In the present invention, a diversion member, for example a diversion column 20 shown in FIG. 3, is further arranged in the container 14 and is directed to the liquid inlet port 18. The column 20 comprises a locating portion 21 positioned on the base 11 of the casing 10, a post portion 22 extending from the locating portion 21 toward the liquid inlet port 18, and an end portion 23 further extending from the post portion 22 into the liquid inlet portion 18. In the preferred embodiment of the present invention, the end portion 23 is tapered from a bottom to an apex thereof, so that liquid enters the container 14 along a sloped outer surface of the tapered end portion 23. As a result, the liquid is led to and orderly flows on the base 11 to have effective heat exchange with the base 11.

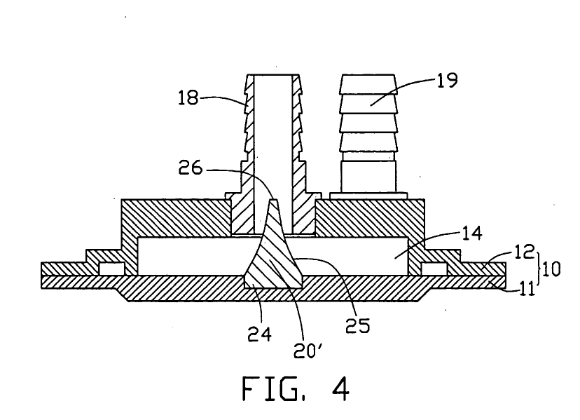

FIG. 4 shows another type of diversion member, for example a diversion block 20′, which is used to guide liquid into the container 14. The diversion block 20′ comprises a bottom portion 24 positioned on the base 11 of the casing 11. The diversion block 20′ extends toward the liquid inlet port 18, with a top portion 26 thereof entering the liquid inlet port 18. The diversion block 20′ is tapered from the bottom portion 24 to the top portion 26, to thereby define a concave peripheral surface 25 therebetween. Thus, the liquid enters the container 14 along the concave peripheral surface 25, and is guided to orderly flow on the base 11 for great heat exchange with the base 11. Certainly, a convex peripheral surface can also perform what the concave surface 25 does.

Additionally, the diversion member of the liquid cooling device, whether it is the diversion column 20 or the diversion block 20′, is positioned on the base 11 which intimately contacts the cooled component (not shown). Thus, part of heat, accumulated on the base 11, is transferred to the diversion member, thereby decreasing the temperature of the base 11. Moreover, the diversion member enlarges the heat exchange surface of the device for greater heat exchange efficiency.

It is understood that the invention may be embodied in other forms without departing from the spirit thereof Thus, the present example and embodiment is to be considered in all respects as illustrative and not restrictive, and the invention is not to be limited to the details given herein.

1. A liquid cooling device comprising:
a casing for accommodating liquid therein, having a liquid inlet port in communication therewith; and
a diversion member extending from a base of the casing into the liquid inlet port and at least having a portion in the liquid inlet port tapered, for leading liquid from the liquid inlet port to the base of the casing.

2. The liquid cooling device of claim 1, wherein the casing comprises a lid covering the base. The liquid cooling device of claim 2, wherein the liquid inlet is formed at the lid.

3. The liquid cooling device of claim 3, wherein the liquid inlet is formed at a middle of the lid.

4. The liquid cooling device of claim 1 wherein the diversion member is post-shaped, comprising a locating portion positioned to the base, a post portion extending from the locating portion toward the liquid inlet port, and an end portion further extending from the post portion.

5. The liquid cooling device of claim 5, wherein the end portion of the diversion member extends into the liquid inlet port.

6. The liquid cooling device of claim 1, wherein the diversion member is wholly tapered, and has its apex extended into the liquid inlet port.

7. A liquid cooling device comprising:
a container accommodating liquid therein;
a liquid inlet port and a liquid outlet port provided on and communicating with the container,
a liquid loop with opposite ends thereof connecting with the inlet port and the outlet port provided exterior of the container; and
a diversion member provided between the inlet port and the container and comprising an inclined surface for leading the liquid from the inlet port to the container.

8. A liquid cooling device comprising:
a container accommodating liquid therein;
a heat-generating-source contact surface defined next to said container to transmit heat to said liquid therethrough;
a liquid inlet port and a liquid outlet port provided beside said container and communicating with said container to allow said liquid flowing therethrough along a first direction angular with said contact surface;
a liquid circulation route located outside of said container and having opposite ends connecting with said inlet and outlet ports respectively, and
a diversion member extending in said inlet port and providing at least one guide surface to reroute said flowing of said liquid in said inlet port from said first direction to a second direction parallel to said contact surface.

9. The liquid cooling device of claim 5, wherein said diversion member is disposed next to said contact surface and extends into said inlet port.
